(19) United States
(12) Patent Application Publication
(10) Pub. No.: US 2026/0110959 A1
(43) Pub. Date: Apr. 23, 2026

(54) PHOTOMASK AND METHOD OF MANUFACTURING THE SAME

(71) Applicant: Samsung Display Co., LTD., Yongin-si (KR)

(72) Inventors: Jae Jin CHA, Yongin-si (KR); Hyun Woo KIM, Yongin-si (KR); Hyung June KIM, Yongin-si (KR); Kwan Soo CHOI, Yongin-si (KR)

(21) Appl. No.: 19/244,573

(22) Filed: Jun. 20, 2025

(30) Foreign Application Priority Data
Oct. 22, 2024 (KR) 10-2024-0144654

(51) Int. Cl. G03F 1/64

(52) U.S. Cl. CPC G03F 1/64

(57) ABSTRACT

A photomask includes: a base member; a mask member disposed below the base member, the mask member including a light-shielding portion for blocking light incident through the base member and an opening defined by the light-shielding portion and for allowing the light to pass therethrough; and a pellicle disposed below the mask member, the pellicle including a flat portion and a protrusion formed to project from the flat portion.

This application claims priority to Korean Patent Application No. 10-2024-0144654 filed on Oct. 22, 2024, and all the benefits accruing therefrom under 35 U.S.C. § 119, the content of which in its entirety is herein incorporated by reference.

### BACKGROUND

### 1. Field

The present disclosure relates to a photomask and a method of manufacturing the same.

### 2. Description of the Related Art

With the advancement of multimedia, the importance of display devices is increasing. Examples of such display devices include liquid crystal displays (“LCDs”) and organic light-emitting displays (“OLEDs”).

The manufacturing process of a display device includes an exposure process for forming signal lines on a substrate. In the exposure process, a photomask is used to transfer desired patterns onto the substrate. As the linewidths of the signal lines formed on the substrate decrease, the importance of the photomask used in the exposure process to implement such linewidths is gradually increasing.

### SUMMARY

Aspects of the present disclosure provide a photomask and a method of manufacturing the same, which can form signal lines with fine linewidths.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a photomask includes a base member, a mask member disposed below the base member, the mask member including a light-shielding portion, which blocks light incident through the base member and an opening, which is defined by the light-shielding portion and allows the light to pass therethrough, and a pellicle disposed below the mask member, the pellicle including a flat portion and a protrusion formed to project from the flat portion.

The protrusion may be disposed to overlap with the opening in a plan view.

The protrusion may project from the flat portion toward the mask member.

An upper surface of the protrusion may be formed as a curved surface, and an uppermost portion of the protrusion may overlap with a center of the opening in the plan view.

A thickness of the protrusion may be smaller than a thickness of the flat portion.

A thickness from a lower surface of the flat portion to an uppermost portion of the protrusion may be 3.2 micrometers (μm) to 3.9 μm.

The protrusion may include an upper protrusion projecting from an upper surface of the flat portion toward the mask member, and a lower protrusion projecting from a lower surface of the flat portion in a direction away from the mask member.

An upper surface of the upper protrusion and a lower surface of the lower protrusion may be formed as curved surfaces, and an uppermost portion of the upper protrusion and a lowermost portion of the lower protrusion may overlap with a center of the opening in the plan view.

A thickness of the upper protrusion and a thickness of the lower protrusion may each be greater than a thickness of the flat portion.

A thickness of the upper protrusion and a thickness of the lower protrusion may be equal to each other.

A curvature of an upper surface of the upper protrusion and a curvature of a lower surface of the lower protrusion may be equal to each other.

A thickness from an uppermost portion of the upper protrusion to a lowermost portion of the lower protrusion may be 3.2 μm to 3.9 μm.

The photomask further may include a support frame extending downward from a side of the base member, where the support frame may support the pellicle such that the pellicle is spaced apart from the mask member.

According to an aspect of the present disclosure, a method of manufacturing a photomask includes: preparing a pellicle base member, fabricating a pellicle having a flat portion and a protrusion by processing the pellicle base member, and disposing the pellicle below a mask member such that the pellicle is spaced apart from the mask member.

The fabricating of the pellicle may include disposing a photoresist on an upper surface of the pellicle base member, removing a portion of the photoresist via an exposure process, and forming the flat portion and the protrusion by etching a portion of the pellicle base member via an etching process.

The protrusion may project from the flat portion toward the mask member.

The mask member may include a light-shielding portion and an opening defined by the light-shielding portion, and in the disposing of the pellicle, the protrusion may be disposed to overlap with the opening in a plan view.

The fabricating of the pellicle may include disposing a first photoresist on an upper surface of the pellicle base member, removing a portion of the first photoresist via an exposure process, forming a first surface of the flat portion and an upper protrusion by etching a portion of the pellicle base member via an etching process, disposing a second photoresist on a lower surface of the pellicle base member, removing a portion of the second photoresist via an exposure process, and forming a second surface of the flat portion opposite to the first surface and a lower protrusion by etching a portion of the pellicle base member via an etching process.

The upper protrusion may project from an upper surface of the flat portion toward the mask member, and the lower protrusion may project from a lower surface of the flat portion in a direction away from the mask member.

The mask member may include a light-shielding portion and an opening defined by the light-shielding portion, and in the disposing of the pellicle, the upper protrusion and the lower protrusion may be disposed to overlap with the opening in a plan view.

According to the present disclosure, the resolution of a photomask can be effectively improved by increasing the concentration of received light by changing the path of incident light in the photomask, thereby enabling the formation of signal lines with fine linewidths.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic diagram illustrating an exposure process according to one embodiment;

FIG. 2 is a schematic diagram illustrating an exposure apparatus of FIG. 1;

FIG. 3 is a side view of a photomask according to a first embodiment;

FIG. 4 is an enlarged view of portion A of FIG. 3;

FIG. 5 is a diagram illustrating a state where the path of incident light onto the photomask is changed by a pellicle in FIG. 4;

FIG. 6 is a side view illustrating a photomask according to a second embodiment;

FIG. 7 is an enlarged view of portion B of FIG. 6;

FIG. 8 is a diagram illustrating a state where the path of incident light onto the photomask is changed by a pellicle in FIG. 7;

FIG. 9 is a diagram illustrating a state where a photoresist is disposed on a pellicle base member in a method of manufacturing the photomask according to the first embodiment;

FIG. 10 is a diagram illustrating a state where portions of the photoresist are removed by an exposure process;

FIG. 11 is a diagram illustrating a state where a flat portion and protrusions of a pellicle are formed via an etching process;

FIG. 12 is a diagram illustrating a state where the pellicle is disposed below a base member and a mask member by a support frame;

FIG. 13 is a diagram illustrating a state where a photoresist is disposed on a pellicle base member in a method of manufacturing the photomask according to the second embodiment;

FIG. 14 is a diagram illustrating a state where portions of the photoresist are removed by an exposure process;

FIG. 15 is a diagram illustrating a state where a flat portion and upper protrusions of a pellicle are formed via an etching process;

FIG. 16 is a diagram illustrating a state where another photoresist is disposed on a surface that is opposite to the surface where the upper protrusions are formed;

FIG. 17 is a diagram illustrating a state where portions of the another photoresist are removed by an exposure process;

FIG. 18 is a diagram illustrating a state where lower protrusions are formed via an etching process; and

FIG. 19 is a diagram illustrating a state where the pellicle is disposed below a base member and a mask member by a support frame.

FIG. 20 is a block diagram of an electronic device according to one embodiment of the present disclosure.

FIG. 21 is a schematic diagram of an electronic device according to various embodiments of the present disclosure.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as “first”, “second”, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, example embodiments of the present disclosure will be described in detail with reference to the accompanying drawings.

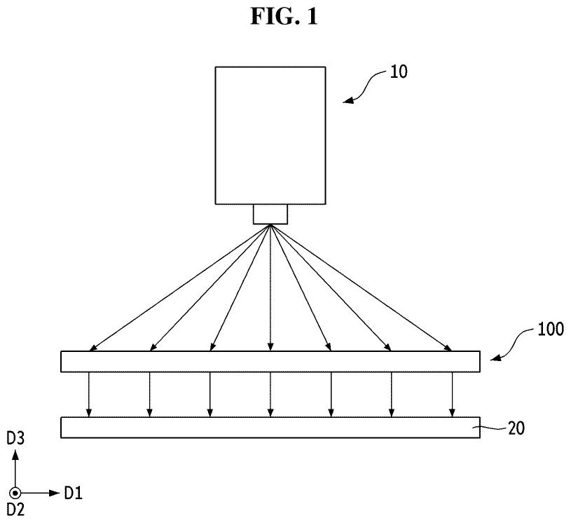

FIG. 1 is a schematic diagram illustrating an exposure process according to one embodiment.

Referring to FIG. 1, the exposure process may be a process of forming signal lines and the like on a substrate 20. In the exposure process, a photomask 100 may be disposed above the substrate 20 in the third direction D3, and light may be irradiated onto the photomask 100 from an exposure apparatus 10 positioned above the photomask 100 in a third direction D3. The light emitted from the exposure apparatus 10 is partially blocked by the light-shielding portion of the photomask 100, while the remaining light passes through the openings of the photomask 100 and sensitizes the photoresist applied to the substrate 20. The openings of the photomask 100 are formed in shapes corresponding to signal lines to be formed on the substrate 20. When the light passing through the openings sensitizes the photoresist applied to the substrate 20, signal lines may be formed on the substrate 20.

In the drawings, a first direction D1 and a second direction D2 may be horizontal directions that intersect with each other. For example, the first and second directions D1 and D2 may be orthogonal to each other. Additionally, the third direction D3 may be, for example, a vertical direction that intersects and is orthogonal to the first and second directions D1 and D2. In this disclosure, the directions indicated by the arrows for the first, second, and third directions D1, D2, and D3 may each be referred to as one side, and the opposite directions may each be referred to as the other side. However, one side and the other side are not particularly limited when they are not explicitly specified.

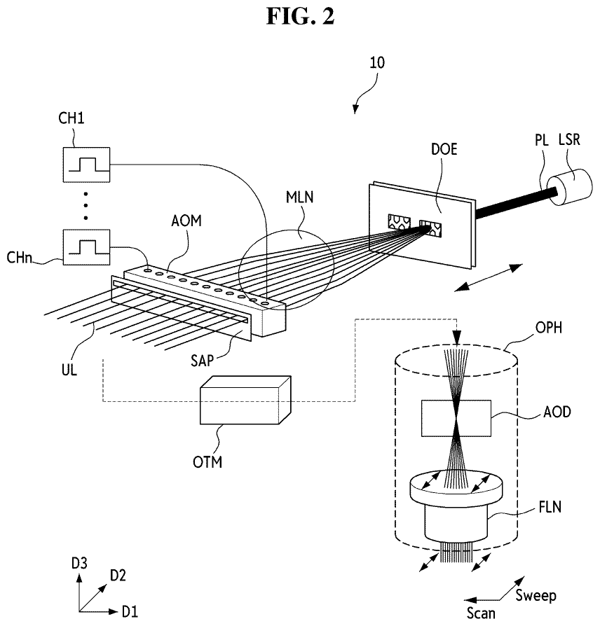

FIG. 2 is a schematic diagram illustrating the exposure apparatus of FIG. 1.

Referring to FIG. 2, the exposure apparatus 10 may include a light source LSR, a diffractive optical element DOE, a module lens MLN, a modulator AOM, an aperture SAP, an optical element OTM, and an optical head OPH.

The light source LSR may include a laser oscillator capable of emitting a laser beam. In some embodiments, the light source LSR may use, as a laser oscillator capable of emitting a laser beam, an excimer laser oscillator emitting KrF, ArF, or XeCl, a gas laser oscillator emitting He, He—Cd, Ar, He—Ne, or HF, a solid-state laser oscillator using a monocrystalline medium such as YAG, YVO₄, forsterite (Mg₂SiO₄), YAlO₃, or GdVO₄, or a polycrystalline (or ceramic) medium with at least one dopant selected from Nd, Yb, Cr, Ti, Ho, Er, Tm, and Ta, or a semiconductor laser oscillator emitting GaN, GaAs, GaAlAs, or InGaAsP.

Here, the laser beam may have energy sufficient to be absorbed by the light-shielding portion of the photomask 100. For example, the laser beam may be appropriately selected from an ultraviolet (“UV”) laser beam, visible laser beam, or infrared (“IR”) laser beam.

A continuous-wave laser beam or a pulsed laser beam may be appropriately used as the laser beam. A pulsed laser beam with an oscillation frequency ranging from several tens of Hz to several kHz is typically used. However, a pulsed laser beam with an extremely high oscillation frequency of 10 MHz or more and a pulse width of several picoseconds (10⁻¹² seconds) or femtoseconds (10⁻¹⁵ seconds) may also be used.

The laser beam emitted from the light source LSR may be a primary laser beam PL. The primary laser beam PL may be divided into a plurality of unit laser beams UL by the diffractive optical element DOE.

The diffractive optical element DOE may divide the primary laser beam PL into a plurality of unit laser beams UL. The number of divided unit laser beams UL is not particularly limited.

The module lens MLN may be disposed between the diffractive optical element DOE and the modulator AOM. The module lens MLN may focus each of the unit laser beams UL onto the modulator AOM.

The modulator AOM may adjust the intensity and/or irradiation duration of the focused unit laser beams UL. The modulator AOM may include an acousto-optic modulator (AOM).

The modulator AOM may include a plurality of channels CH configured to control the respective unit laser beams UL. The channels CH may individually adjust the intensity and/or irradiation duration of the respective unit laser beams UL based on input data.

The aperture SAP may adjust the quantity of the emitted unit laser beams UL and may regulate the unit laser beams UL so that they may be emitted in a uniform direction. The aperture SAP may be formed in a slit shape.

The optical element OTM may be disposed along the optical path between the aperture SAP and the optical head OPH. The optical element OTM may redirect the optical path so that the unit laser beams UL emitted from the aperture SAP may be directed to the optical head OPH.

The optical head OPH, which is a scanning device, may perform reciprocating motion along the first direction D1. While the optical head OPH moves along the first direction D1, the unit laser beams UL may sweep along the second direction D2.

The optical head OPH may include a deflector AOD and a final lens FLN.

The deflector AOD may deflect the unit laser beams UL onto the photomask 100 to perform sweeping. In one embodiment, the deflector AOD may include an acousto-optic deflector (AOD).

The final lens FLN may focus the unit laser beams UL onto the photomask 100.

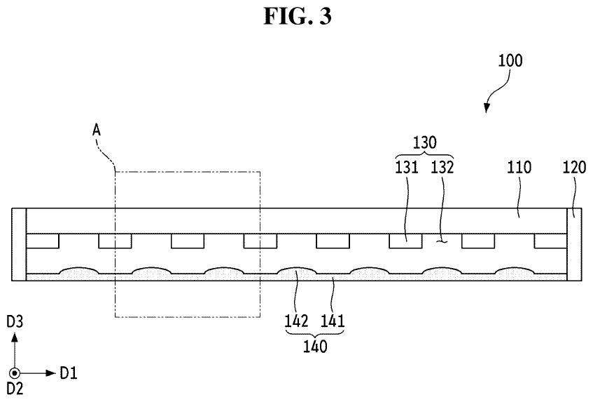

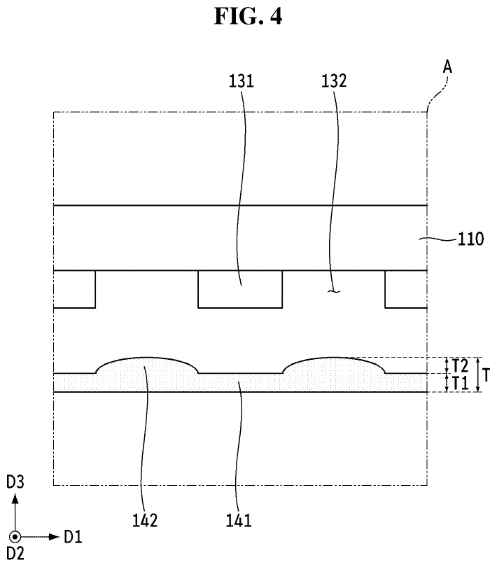

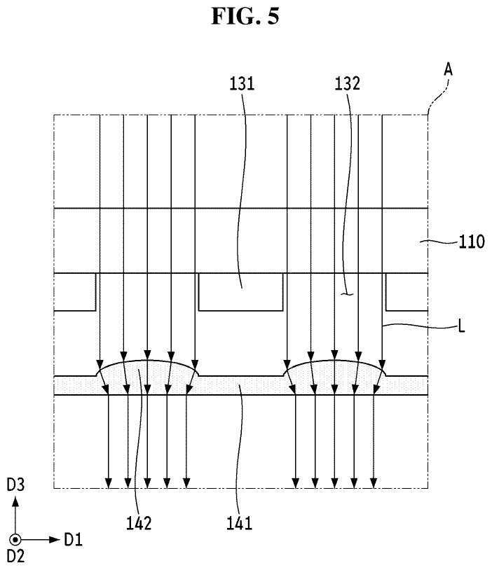

FIG. 3 is a side view of a photomask according to a first embodiment. FIG. 4 is an enlarged view of portion A of FIG. 3. FIG. 5 illustrates a state where the path of incident light entering the photomask of FIG. 4 is changed by a pellicle.

Referring to FIGS. 3 through 5, a photomask 100 according to the first embodiment may include a base member 110, a support frame 120, a mask member 130, and a pellicle 140.

The base member 110 may be formed of a light-transmissive material that allows light L irradiated from the exposure apparatus 10 to pass through. For example, the base member 110 may be a substrate including glass, quartz, sapphire, or ceramic.

The support frame 120 may extend downward in the thickness direction of the base member 110 from the sides of the base member 110. In some embodiments, the support frame 120 may extend downward in the third direction D3 from the sides of the base member 110. The support frame 120 may support the pellicle 140 such that the pellicle 140 may be spaced apart from the mask member 130, which is disposed below the base member 110.

The mask member 130 may block some of the light L irradiated from the exposure apparatus 10 and allow the rest of the light L to pass through to form signal lines on the substrate 20. The mask member 130 may include a light-shielding portion 131 and openings 132 defined by the light-shielding portion 131.

The light-shielding portion 131 may block the light L irradiated from the exposure apparatus 10 and incident on the base member 110. The light-shielding portion 131 may be formed of a material capable of absorbing the light L irradiated from the exposure apparatus 10. For example, the light-shielding portion 131 may be formed of a conductive or insulating material. In one embodiment, the light-shielding portion 131 may be formed using an element such as chromium (Cr), molybdenum (Mo), nickel (Ni), titanium (Ti), cobalt (Co), copper (Cu), or aluminum (Al), an alloy of the element, or a compound such as a nitride, oxide, carbide, or halide, but the present disclosure is not limited thereto.

In some embodiments, when the light-shielding portion 131 is formed of a conductive material, it may be formed using a deposition, sputtering, or chemical vapor deposition (“CVD”) method. In other embodiments, when the light-shielding portion 131 is formed of an insulating material, it may be formed using a coating method.

The light-shielding portion 131 is illustrated as having a single-layer structure, but the present disclosure is not limited thereto. Alternatively, the light-shielding portion 131 may be formed as a multilayer stacked structure as needed.

The openings 132 may allow the light L irradiated from the exposure apparatus 10 and incident on the base member 110 to pass therethrough. A plurality of openings 132 may be provided and may be spaced apart from one another. The openings 132 may be formed via an exposure process. A photoresist (not illustrated) may be disposed on the light-shielding portion 131, and the openings 132 may be formed using the photoresist as a mask. For example, portions of the light-shielding portion 131 not masked by the pattern formed in the photoresist may be removed by an exposure process to form the openings 132. The openings 132 may be areas where portions of the light-shielding portion 131 are removed through the thickness direction of the light-shielding portion 131 by an exposure process. The openings 132 may be formed by an exposure process, but the present disclosure is not limited thereto. Alternatively, in other embodiments, the openings 132 may be formed through a dry or wet etching process.

The pellicle 140 may be disposed below the mask member 130 in the third direction D3 to be spaced apart from the mask member 130. The pellicle 140 may be supported by the support frame 120. The pellicle 140 may protect the base member 110 and the mask member 130 from external contaminants such as dust or resist during an exposure process. The pellicle 140 may include a flat portion 141 and protrusions 142.

The flat portion 141 may be provided in the form of a plate with a certain thickness. The flat portion 141 may have high light transmittance and excellent heat dissipation, strength, durability, and stability. Both sides of the flat portion 141 may be supported by the support frame 120, allowing it to be disposed below and spaced apart from the mask member 130 in the third direction D3.

The protrusions 142 may be formed to protrude from the flat portion 141. The protrusions 142 may be formed of the same material as the flat portion 141 and may be integrally formed with the flat portion 141. The protrusions 142 may have high light transmittance and excellent heat dissipation properties, strength, durability, and stability. A plurality of protrusions 142 may be provided and may overlap with the openings 132. For example, one of the protrusions 142 may overlap with one of the openings 132, while another protrusion 142 may overlap with another opening 132 in a plan view. As used herein, the “plan view” is a view in a thickness direction (third direction DR3) of the photomask 100.

The protrusions 142 may protrude from the flat portion 141 toward the mask member 130. In some embodiments, the protrusions 142 may protrude upward in the third direction D3 from the upper surface of the flat portion 141. The protrusions 142 may protrude toward the openings 132 of the mask member 130.

The upper surfaces of the protrusions 142 may be formed as curved surfaces. For example, the upper surfaces of the protrusions 142 may have a semi-circular or semi-elliptical outer shape. The uppermost portions, in the third direction D3, of the upper surfaces of the protrusions 142 may overlap with the centers of the openings 132 in a plan view. The length of the protrusions 142 in the first direction D1 may correspond to the length of the openings 132 in the first direction D1.

The protrusions 142 may change the path of light L passing through the openings 132. The light L irradiated from the exposure apparatus 10 and passing through the openings 132 may have its path altered toward the centers of the protrusions 142 as it passes through the upper surfaces of the protrusions 142. Since the protrusions 142 are formed in a semi-circular or semi-elliptical shape, they may act as convex lenses, changing the path of the light L toward the centers of the protrusions 142. In this manner, the protrusions 142 may increase the amount of received light, i.e., light transmittance, by altering the path of the light L incident on the photomask 100 toward the centers of the protrusions 142, thereby improving the resolution of the photomask 100 and increasing light efficiency.

A thickness T2 of the protrusions 142 may be formed smaller than a thickness T1 of the flat portion 141. A thickness T from the lower surface of the flat portion 141 to the uppermost portions of the protrusions 142 may be 3.2 μm to 3.9 μm. When the thickness T is 3.2 μm, the light transmittance of the pellicle 140 is 96.38%, and when the thickness T is 3.9 μm, the light transmittance of the pellicle 140 is 96.76%. On the other hand, when the thickness T is 3.15 μm, the light transmittance of the pellicle 140 is 94.39%, and when the thickness T is 3.95 μm, the light transmittance of the pellicle 140 is 94.84%. Since the pellicle 140 is desirable to have a light transmittance of 96% or higher, the thickness T from the lower surface of the flat portion 141 to the uppermost portions of the protrusions 142 in an embodiment may be 3.2 μm to 3.9 μm. As used herein, the thickness is measured in the third direction DR3.

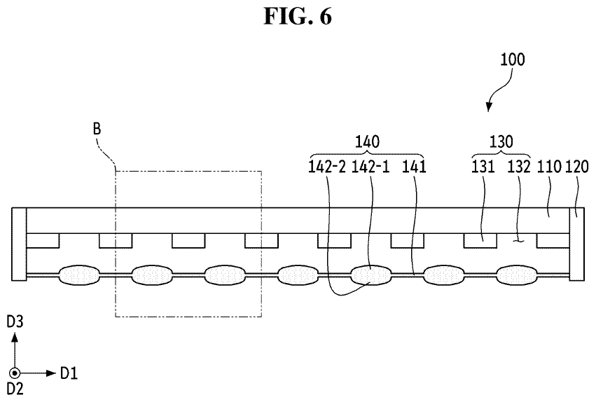

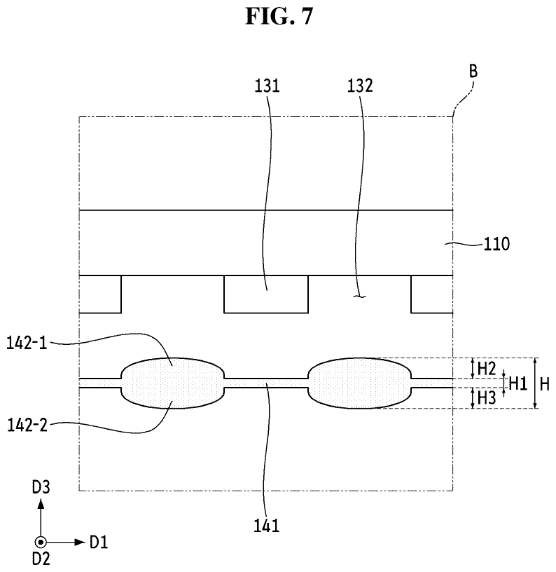

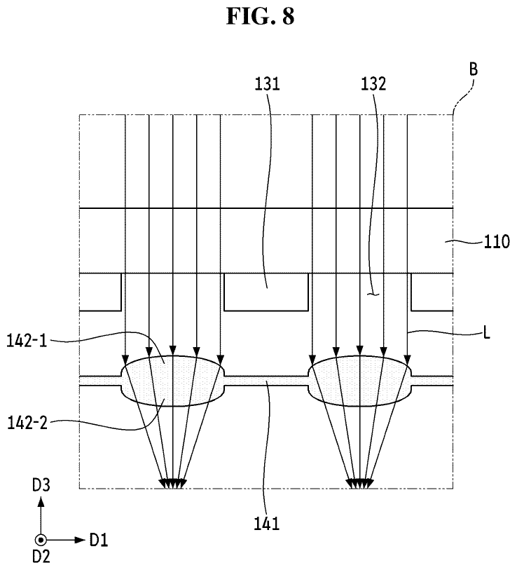

FIG. 6 is a side view of a photomask according to a second embodiment. FIG. 7 is an enlarged view of portion B of FIG. 6. FIG. 8 illustrates a state where the path of incident light entering the photomask of FIG. 7 is changed by a pellicle.

Referring to FIGS. 6 through 8, a photomask 100 according to the second embodiment may include a base member 110, a support frame 120, a mask member 130, and a pellicle 140.

The base member 110 may be formed of a light-transmissive material that allows light L irradiated from the exposure apparatus 10 to pass therethrough. For example, the base member 110 may be a substrate including glass, quartz, sapphire, or ceramic.

The support frame 120 may extend downward in the thickness direction of the base member 110 from the sides of the base member 110. In some embodiments, the support frame 120 may extend downward in the third direction D3 from the sides of the base member 110. The support frame 120 may support the pellicle 140 such that the pellicle 140 may be spaced apart from the mask member 130, which is disposed below the base member 110.

The mask member 130 may block some of the light L irradiated from the exposure apparatus 10 and allow the rest of the light L to pass therethrough to form signal lines on the substrate 20. The mask member 130 may include a light-shielding portion 131 and openings 132 defined by the light-shielding portion 131.

The light-shielding portion 131 may block the light L irradiated from the exposure apparatus 10 and incident on the base member 110. The light-shielding portion 131 may be formed of a material capable of absorbing the light L irradiated from the exposure apparatus 10. For example, the light-shielding portion 131 may be formed of a conductive or insulating material. In one embodiment, the light-shielding portion 131 may be formed using an element such as Cr, Mo, Ni, Ti, Co, Cu, or Al, an alloy of the element, or a compound such as a nitride, oxide, carbide, or halide, but the present disclosure is not limited thereto.

In some embodiments, when the light-shielding portion 131 is formed of a conductive material, it may be formed using a deposition, sputtering, or chemical vapor deposition (CVD) method. In other embodiments, when the light-shielding portion 131 is formed of an insulating material, it may be formed using a coating method.

The light-shielding portion 131 is illustrated as having a single-layer structure, but the present disclosure is not limited thereto. Alternatively, the light-shielding portion 131 may be formed as a multilayer stacked structure as needed.

The openings 132 may allow the light L irradiated from the exposure apparatus 10 and incident through the base member 110 to pass through the openings 132. A plurality of openings 132 may be provided and may be spaced apart from one another. The openings 132 may be formed via an exposure process. A photoresist (not illustrated) may be disposed on the light-shielding portion 131, and the openings 132 may be formed using the photoresist as a mask. For example, portions of the light-shielding portion 131 not masked by the pattern formed in the photoresist may be removed by an exposure process to form the openings 132. The openings 132 may be areas where portions of the light-shielding portion 131 are removed through the thickness direction of the light-shielding portion 131 by an exposure process. The openings 132 may be formed by an exposure process, but the present disclosure is not limited thereto. Alternatively, in other embodiments, the openings 132 may be formed through a dry or wet etching process.

The pellicle 140 may be disposed below the mask member 130 in the third direction D3 to be spaced apart from the mask member 130. The pellicle 140 may be supported by the support frame 120. The pellicle 140 may protect the base member 110 and the mask member 130 from external contaminants such as dust or resist during an exposure process. The pellicle 140 may include a flat portion 141 and protrusions 142.

The flat portion 141 may be provided in the form of a plate with a certain thickness. The flat portion 141 may have high light transmittance and excellent heat dissipation, strength, durability, and stability. Both sides of the flat portion 141 may be supported by the support frame 120, allowing it to be disposed below and spaced apart from the mask member 130 in the third direction D3.

The protrusions 142 may be formed to protrude from the flat portion 141. The protrusions 142 may be formed of the same material as the flat portion 141 and may be integrally formed with the flat portion 141. The protrusions 142 may have high light transmittance and excellent heat dissipation properties, strength, durability, and stability. A plurality of protrusions 142 may be provided and may overlap with the openings 132. For example, one of the protrusions 142 may overlap with one of the openings 132, while another protrusion 142 may overlap with another opening 132 in a plan view.

The protrusions 142 may include upper protrusions 142-1 and lower protrusions 142-2.

The upper protrusions 142-1 may protrude from the upper surface of the flat portion 141 toward the mask member 130. In some embodiments, the upper protrusions 142-1 may protrude upward in the third direction D3 from the upper surface of the flat portion 141. The upper protrusions 142-1 may protrude toward the openings 132 of the mask member 130.

The upper surfaces of the upper protrusions 142-1 may be formed as curved surfaces. For example, the upper surfaces of the upper protrusions 142-1 may have a semi-circular or semi-elliptical outer shape. The uppermost portions, in the third direction D3, of the upper surfaces of the upper protrusions 142-1 may overlap with the centers of the openings 132 in a plan view. The length of the upper protrusions 142-1 in the first direction D1 may correspond to the length of the openings 132 in the first direction D1.

The lower protrusions 142-2 may protrude from the lower surface of the flat portion 141 in a downward direction away from the mask member 130. In some embodiments, the lower protrusions 142-2 may protrude downward in the third direction D3 from the lower surface of the flat portion 141.

The lower surfaces of the lower protrusions 142-2 may be formed as curved surfaces. For example, the lower surfaces of the lower protrusions 142-2 may have a semi-circular or semi-elliptical outer shape. The curvature of the lower surfaces of the lower protrusions 142-2 may be identical to that of the upper surfaces of the upper protrusions 142-1. The lowermost portions, in the third direction D3, of the lower surfaces of the lower protrusions 142-2 may overlap with the centers of the openings 132 in a plan view. The length of the lower protrusions 142-2 in the first direction D1 may correspond to the length of the openings 132 in the first direction D1.

The protrusions 142 may change the path of light L passing through the openings 132. The light L irradiated from the exposure apparatus 10 and passing through the openings 132 may have its path altered toward the centers of the protrusions 142 as it passes through the upper surfaces of the upper protrusions 142-1. The light L passing through the upper protrusions 142-1 may have its path further altered toward the centers of the protrusions 142 as it passes through the lower surfaces of the lower protrusions 142-2. Since the protrusions 142 are formed in a circular or elliptical shape, they may act as convex lenses, changing the path of the light L toward the centers of the protrusions 142. In this manner, the protrusions 142 may increase the amount/concentration of received light, i.e., light transmittance, by altering the path of the light L incident on the photomask 100 toward the centers of the protrusions 142, thereby improving the resolution of the photomask 100 and increasing light efficiency.

A thickness H2 of the upper protrusions 142-1 and a thickness H3 of the lower protrusions 142-2 may each be greater than a thickness H1 of the flat portion 141. The thicknesses H2 and H3 may be equal. A thickness H from the uppermost portions of the upper protrusions 142-1 to the lowermost portions of the lower protrusions 142-2 may be 3.2 μm to 3.9 μm. When the thickness H is 3.2 μm, the light transmittance of the pellicle 140 is 96.38%, and when the thickness H is 3.9 μm, the light transmittance of the pellicle 140 is 96.76%. On the other hand, when the thickness H is 3.15 μm, the light transmittance of the pellicle 140 is 94.39%, and when the thickness H is 3.95 μm, the light transmittance of the pellicle 140 is 94.84%. Since the pellicle 140 requires a light transmittance of 96% or higher, the thickness H from the uppermost portions of the upper protrusions 142-1 to the lowermost portions of the lower protrusions 142-2 may be 3.2 μm to 3.9 μm.

A method of manufacturing the photomask according to the first embodiment will hereinafter be described with reference to the drawings.

The method of manufacturing the photomask according to the first embodiment may include the operations of: preparing a pellicle base member FB; fabricating the pellicle 140 having the flat portion 141 and the protrusions 142 by processing the pellicle base member FB; and disposing the pellicle 140 below the mask member 130 to be spaced apart from the mask member 130.

First, the operation of preparing the pellicle base member FB may be performed. The pellicle base member FB may be the raw material of the pellicle 140 before being processed into the flat portion 141 and the protrusions 142. The pellicle base member FB may be provided in the form of a plate with a certain thickness and may have high light transmittance, excellent heat dissipation properties, strength, durability, and stability.

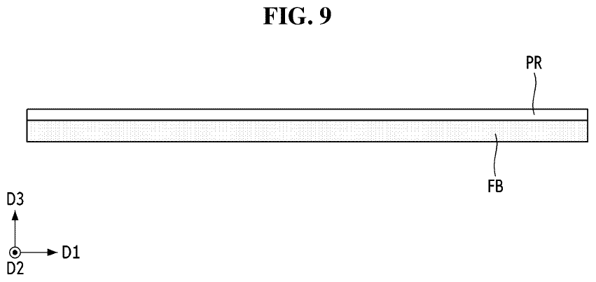

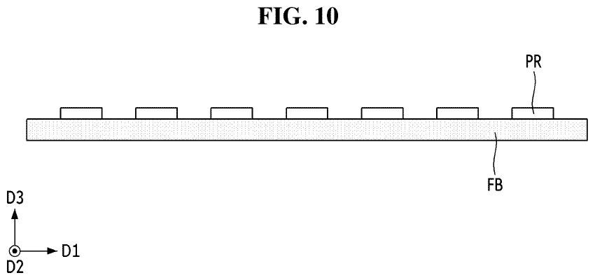

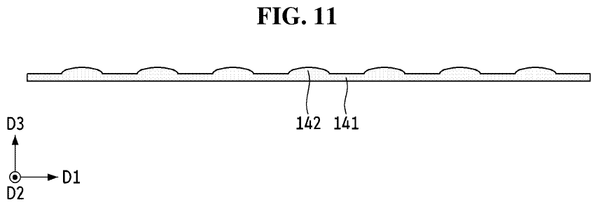

FIG. 9 illustrates a state where a photoresist is disposed on the upper surface of a pellicle base member in the method of manufacturing the photomask according to the first embodiment. FIG. 10 illustrates a state where portions of the photoresist are removed via an exposure process. FIG. 11 illustrates a state where the flat portion and the protrusions of a pellicle are formed via an etching process.

Referring to FIGS. 9 through 11, the operation of fabricating the pellicle 140 having the flat portion 141 and the protrusions 142 by processing the pellicle base member FB may include: disposing a photoresist PR on the upper surface of the pellicle base member FB; removing portions of the photoresist PR via an exposure process; and forming the flat portion 141 and the protrusions 142 by etching portions of the pellicle base member FB via an etching process.

Referring to FIG. 9, the photoresist PR may be disposed on the upper surface of the pellicle base member FB. A mask (not illustrated) having a pattern corresponding to the flat portion 141 may be disposed above the photoresist PR.

Referring to FIG. 10, portions of the photoresist PR may be removed via an exposure process. When light is irradiated onto the photoresist PR from a separate exposure apparatus (not illustrated), some of the light may be blocked by the mask (not illustrated), while some of the light may pass through the mask and sensitize the photoresist PR. Since the mask includes the pattern corresponding to the flat portion 141, the photoresist PR may have an opening pattern corresponding to the flat portion 141, and the photoresist PR may remain in positions corresponding to the protrusions 142.

Referring to FIG. 11, the flat portion 141 and the protrusions 142 may be formed via an etching process. The pellicle base member FB may be etched only in areas where openings in the photoresist PR are formed, thereby forming the flat portion 141. Since the areas where the photoresist PR remains are not etched, they may protrude relative to the flat portion 141. Thus, the protrusions 142 may be formed in the areas of the pellicle base member FB where the photoresist PR remains.

Once the pellicle 140, having the flat portion 141 and the protrusions 142, is fabricated in this manner, the operation of disposing the pellicle 140 below the mask member 130 may be performed.

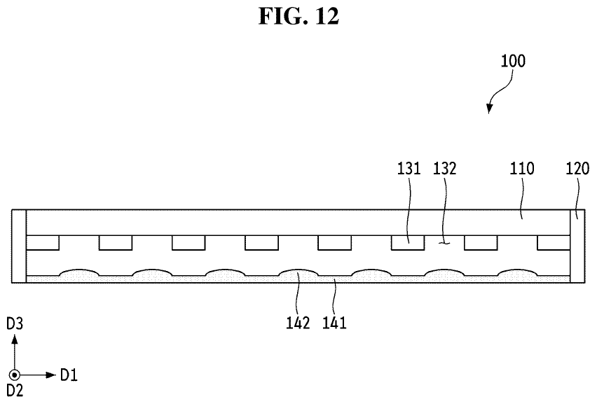

FIG. 12 illustrates a state where the pellicle of FIG. 11 is disposed below a base member and a mask member by a support frame.

Referring to FIG. 12, the pellicle 140 may be supported by the support frame 120 and disposed below the mask member 130 to be spaced apart from the mask member 130. The pellicle 140 may be disposed such that a plurality of protrusions 142 may face the mask member 130 and overlap with a plurality of openings 132 of the mask member 130 in a plan view.

A method of manufacturing the photomask according to the second embodiment will hereinafter be described with reference to the drawings.

The method of manufacturing the photomask according to the second embodiment may include the steps of: preparing a pellicle base member FB; fabricating the pellicle 140 having the flat portion 141 and the protrusions 142 by processing the pellicle base member FB; and disposing the pellicle 140 below the mask member 130 to be spaced apart from the mask member 130.

First, the operation of preparing the pellicle base member FB may be performed. The pellicle base member FB may be the raw material of the pellicle 140 before being processed into the flat portion 141 and the protrusions 142. The pellicle base member FB may be provided in the form of a plate with a certain thickness and may have high light transmittance, excellent heat dissipation properties, strength, durability, and stability.

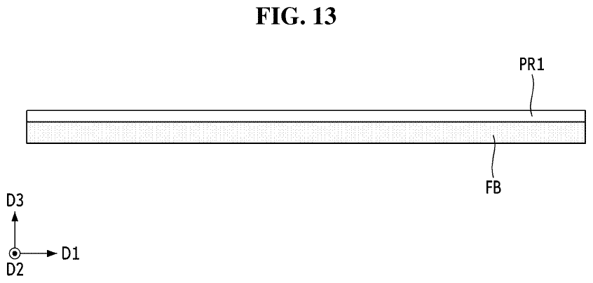

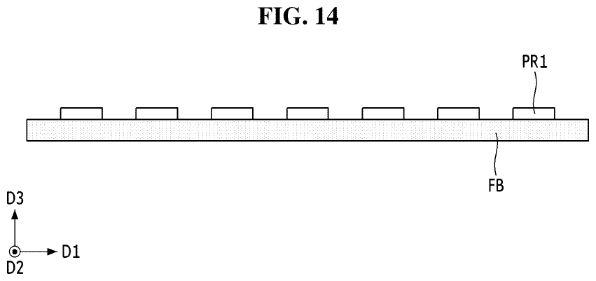

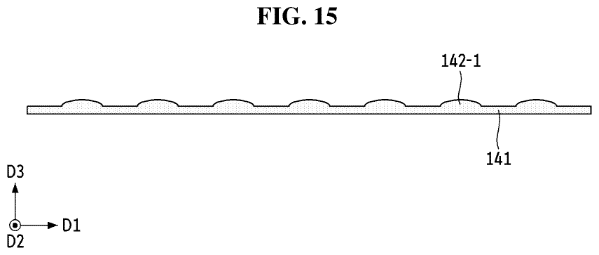

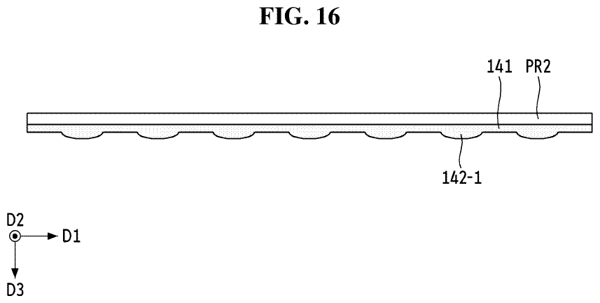

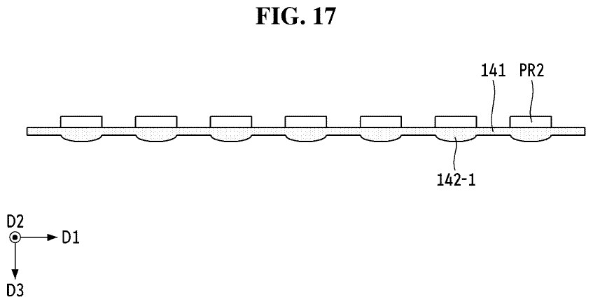

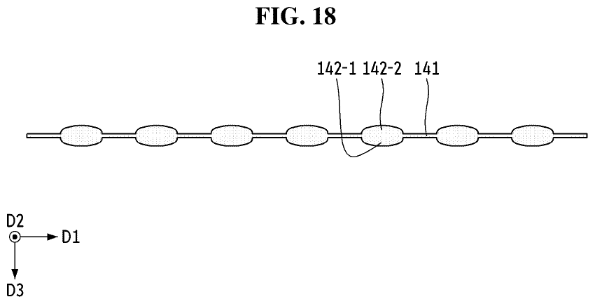

FIG. 13 illustrates a state where a photoresist is disposed on the upper surface of the pellicle base member in the method of manufacturing the photomask according to the second embodiment. FIG. 14 illustrates a state where portions of the photoresist are removed via an exposure process. FIG. 15 illustrates a state where the flat portion and the upper protrusions of the pellicle are formed via an etching process. FIG. 16 illustrates a state where another photoresist is disposed on a surface opposite to the surface where the flat portion and the upper protrusions are formed. FIG. 17 illustrates a state where portions of the another photoresist are removed via an exposure process. FIG. 18 illustrates a state where lower protrusions are formed via an etching process.

Referring to FIGS. 13 through 18, the operation of fabricating the pellicle 140 having the flat portion 141 and the protrusions 142 by processing the pellicle base member FB may include: disposing a first photoresist PR1 on the upper surface of the pellicle base member FB; removing portions of the first photoresist PR1 via an exposure process; forming one surface of the flat portion 141 and the upper protrusions 142-1 by etching portions of the pellicle base member FB via an etching process; disposing a second photoresist PR2 on the lower surface of the pellicle base member FB; removing portions of the second photoresist PR2 via an exposure process; and forming the other surface of the flat portion 141 and the lower protrusions 142-2 by etching portions of the pellicle base member FB via an etching process.

Referring to FIG. 13, the first photoresist PR1 may be disposed on the upper surface of the pellicle base member FB. A mask (not illustrated) having a pattern corresponding to the flat portion 141 may be disposed above the first photoresist PR1.

Referring to FIG. 14, portions of the first photoresist PR1 may be removed via an exposure process. When light is irradiated onto the first photoresist PR1 from a separate exposure apparatus (not illustrated), some of the light may be blocked by a mask (not illustrated), while some of the light may pass through the mask and sensitize the first photoresist PR1. Since the mask includes a pattern corresponding to the flat portion 141, the first photoresist PR1 may have an opening pattern corresponding to the flat portion 141, and the first photoresist PR1 may remain in positions corresponding to the upper protrusions 142-1.

Referring to FIG. 15, one surface of the flat portion 141 and the upper protrusions 142-1 may be formed via an etching process. The pellicle base member FB may be etched only in areas where openings in the first photoresist PR1 are formed, thereby forming one surface of the flat portion 141. Since the areas where the first photoresist PR1 remains are not etched, they may protrude relative to the flat portion 141. Thus, the upper protrusions 142-1 may be formed in the areas of the pellicle base member FB where the first photoresist PR1 remains.

FIGS. 16 through 18 illustrate steps performed on the pellicle base member FB after flipping over the pellicle base member FB of FIG. 15.

Referring to FIG. 16, the second photoresist PR2 may be disposed below (above in the figure) the pellicle base member FB. A mask (not illustrated) having a pattern corresponding to the flat portion 141 may be disposed below (above in the figure) the second photoresist PR2.

Referring to FIG. 17, portions of the second photoresist PR2 may be removed via an exposure process. When light is irradiated onto the second photoresist PR2 from a separate exposure apparatus (not illustrated), some of the light may be blocked by the mask (not illustrated), while some of the light may pass through the mask and sensitize the second photoresist PR2. Since the mask includes the pattern corresponding to the flat portion 141, the second photoresist PR2 may have an opening pattern corresponding to the flat portion 141, and the second photoresist PR2 may remain in positions corresponding to the lower protrusions 142-2.

Referring to FIG. 18, the other surface of the flat portion 141 and the lower protrusions 142-2 may be formed via an etching process. The pellicle base member FB may be etched only in areas where openings in the second photoresist PR2 are formed, thereby forming the other surface of the flat portion 141. Since the areas where the second photoresist PR2 remains are not etched, they may protrude relative to the flat portion 141. Thus, the lower protrusions 142-2 may be formed in the areas of the pellicle base member FB where the second photoresist PR2 remains.

Once the pellicle 140, having the flat portion 141, the upper protrusions 142-1, and the lower protrusions 142-2, is fabricated in this manner, the operation of disposing the pellicle 140 below the mask member 130 may be performed.

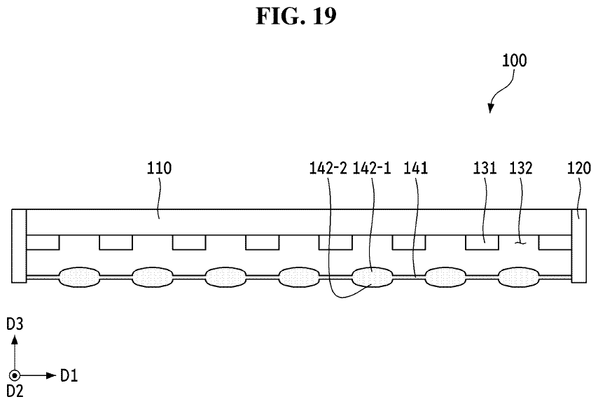

FIG. 19 illustrates a state where the pellicle of FIG. 18 is disposed below a base member and a mask member by a support frame.

Referring to FIG. 19, the pellicle 140 may be supported by the support frame 120 and disposed below the mask member 130 to be spaced apart from the mask member 130. The pellicle 140 may be disposed such that a plurality of upper protrusions 142-1 may face the mask member 130, and the upper protrusions 142-1 and the lower protrusions 142-2 may be disposed to overlap with a plurality of openings 132 of the mask member 130 in a plan view.

The display device according to one embodiment of the present disclosure can be applied to various electronic devices. The electronic device according to the one embodiment of the present disclosure includes the display device described above, and may further include modules or devices having additional functions in addition to the display device.

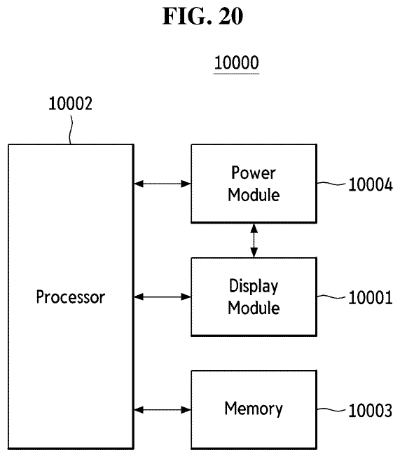

FIG. 20 is a block diagram of an electronic device according to one embodiment of the present disclosure.

Referring to FIG. 20, the electronic device 10000 according to one embodiment of the present disclosure may include a display module 10001, a processor 10002, a memory 10003, and a power module 10004.

The processor 10002 may include at least one of a central processing unit (“CPU”), an application processor (“AP”), a graphic processing unit (“GPU”), a communication processor (“CP”), an image signal processor (“ISP”), and a controller.

The memory 10003 may store data information necessary for the operation of the processor 10002 or the display module 10001. When the processor 10002 executes an application stored in the memory 10003, an image data signal and/or an input control signal is transmitted to the display module 10001, and the display module 10001 can process the received signal and output image information through a display screen.

The power module 10004 may include a power supply module such as, for example a power adapter or a battery, and a power conversion module that converts the power supplied by the power supply module to generate power necessary for the operation of the electronic device 10000.

At least one of the components of the electronic device 10000 according to the one embodiment of the present disclosure may be included in the display device according to the embodiments of the present disclosure. In addition, some modules of the individual modules functionally included in one module may be included in the display device, and other modules may be provided separately from the display device. For example, the display device may include the display module 10001, and the processor 10002, the memory 10003, and the power module 10004 may be provided in the form of other devices within the electronic device 10000 other than the display device.

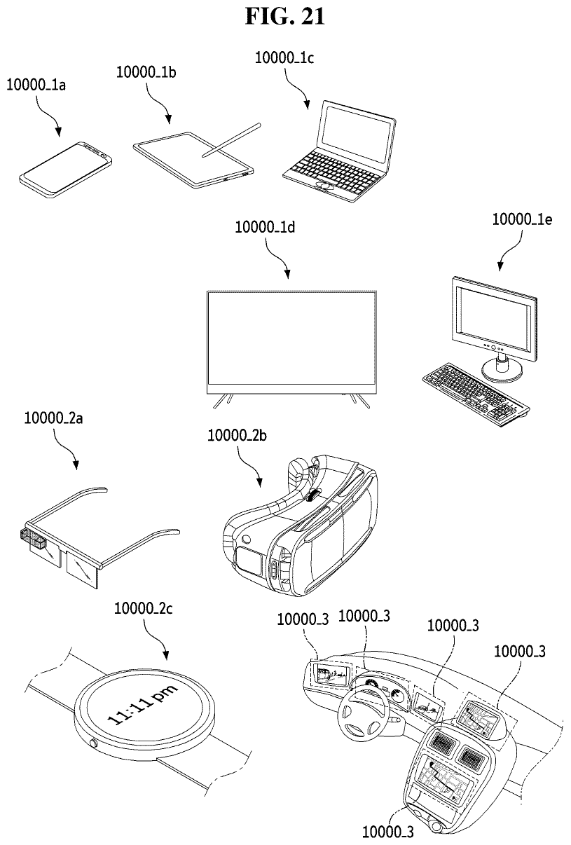

FIG. 21 is a schematic diagram of an electronic device according to various embodiments of the present disclosure.

Referring to FIG. 21, various electronic devices to which display devices according to embodiments of the present disclosure are applied may include not only image display electronic devices such as a smart phone 10000_1a, a tablet personal computer (PC) 10000_1b, a laptop 10000_1c, a TV 10000_1d, and a desk monitor 10000_1e, but also wearable electronic devices including display modules such as, for example smart glasses 10000_2a, a head mounted display 10000_2b, and a smart watch 10000_2c, and vehicle electronic devices 10000_3 including display modules such as a Center Information Display (CID) and a room mirror display arranged on a dashboard, center fascia, and dashboard of an automobile.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A photomask comprising:
a base member;
a mask member disposed below the base member, the mask member including a light-shielding portion, which blocks light incident through the base member and an opening, which is defined by the light-shielding portion and allows the light to pass therethrough; and
a pellicle disposed below the mask member, the pellicle including a flat portion and a protrusion formed to project from the flat portion.

2. The photomask of claim 1, wherein the protrusion is disposed to overlap with the opening in a plan view.

3. The photomask of claim 2, wherein the protrusion projects from the flat portion toward the mask member.

4. The photomask of claim 3, wherein
an upper surface of the protrusion is formed as a curved surface, and
an uppermost portion of the protrusion overlaps with a center of the opening in the plan view.

5. The photomask of claim 3, wherein a thickness of the protrusion is smaller than a thickness of the flat portion.

6. The photomask of claim 3, wherein a thickness from a lower surface of the flat portion to an uppermost portion of the protrusion is 3.2 micrometers (μm) to 3.9 μm.

7. The photomask of claim 2, wherein the protrusion includes:
an upper protrusion projecting from an upper surface of the flat portion toward the mask member; and
a lower protrusion projecting from a lower surface of the flat portion in a direction away from the mask member.

8. The photomask of claim 7, wherein
an upper surface of the upper protrusion and a lower surface of the lower protrusion are formed as curved surfaces, and
an uppermost portion of the upper protrusion and a lowermost portion of the lower protrusion overlap with a center of the opening in the plan view.

9. The photomask of claim 7, wherein a thickness of the upper protrusion and a thickness of the lower protrusion are each greater than a thickness of the flat portion.

10. The photomask of claim 7, wherein a thickness of the upper protrusion and a thickness of the lower protrusion are equal to each other.

11. The photomask of claim 7, wherein a curvature of an upper surface of the upper protrusion and a curvature of a lower surface of the lower protrusion are equal to each other.

12. The photomask of claim 7, wherein a thickness from an uppermost portion of the upper protrusion to a lowermost portion of the lower protrusion is 3.2 μm to 3.9 μm.

13. The photomask of claim 1, further comprising:
a support frame extending downward from a side of the base member,
wherein the support frame supports the pellicle such that the pellicle is spaced apart from the mask member.

14. A method of manufacturing a photomask, comprising:
preparing a pellicle base member;
fabricating a pellicle having a flat portion and a protrusion by processing the pellicle base member; and
disposing the pellicle below a mask member such that the pellicle is spaced apart from the mask member.

15. The method of claim 14, wherein the fabricating of the pellicle comprises:
disposing a photoresist on an upper surface of the pellicle base member;
removing a portion of the photoresist via an exposure process; and
forming the flat portion and the protrusion by etching a portion of the pellicle base member via an etching process.

16. The method of claim 15, wherein the protrusion projects from the flat portion toward the mask member.

17. The method of claim 15, wherein
the mask member includes a light-shielding portion and an opening defined by the light-shielding portion, and
in the disposing of the pellicle, the protrusion is disposed to overlap with the opening in a plan view.

18. The method of claim 14, wherein the fabricating of the pellicle comprises:
disposing a first photoresist on an upper surface of the pellicle base member;
removing a portion of the first photoresist via an exposure process;
forming a first surface of the flat portion and an upper protrusion by etching a portion of the pellicle base member via an etching process;
disposing a second photoresist on a lower surface of the pellicle base member; removing a portion of the second photoresist via an exposure process; and
forming a second surface of the flat portion opposite to the first surface and a lower protrusion by etching a portion of the pellicle base member via an etching process.
wherein the upper protrusion projects from an upper surface of the flat portion toward the mask member, and
the lower protrusion projects from a lower surface of the flat portion in a direction away from the mask member.

19. The method of claim 18, wherein
the mask member includes a light-shielding portion and an opening defined by the light-shielding portion, and
in the disposing of the pellicle, the upper protrusion and the lower protrusion are disposed to overlap with the opening in a plan view.

20. An electronic device comprising:
a display device manufactured by a photomask;
the photomask comprising:
a base member;
a mask member disposed below the base member, the mask member including a light-shielding portion, which blocks light incident through the base member and an opening, which is defined by the light-shielding portion and allows the light to pass therethrough; and
a pellicle disposed below the mask member, the pellicle including a flat portion and a protrusion formed to project from the flat portion.
